(19) United States
(12) Patent Application Publication
(10) Pub. No.: US 2009/0096452 A1
(43) Pub. Date: Apr. 16, 2009

(54) HELIUM COMPRESSOR WITH CONTROL FOR REDUCED POWER CONSUMPTION

(76) Inventors: Russell Peter Gore, Abingdon (GB); Rolf Heinrichs, Roettenbach (DE); Trevor Bryan Husband, Banbury (GB); Philip Alan Charles Walton, Oxon (GB)

Correspondence Address: SCHIFF HARDIN, LLP;PATENT DEPARTMENT, 6600 SEARS TOWER, CHICAGO, IL, 60606-6473, US

(21) Appl. No.: 12/238,817

(22) Filed: Sep. 26, 2008

(30) Foreign Application Priority Data
Oct. 15, 2007 (GB) 0720084.3

(51) Int. Cl. G01R 33/34

(52) U.S. Cl. 324/318

(57) ABSTRACT

A magnetic resonance imaging system has a superconducting magnet housed within a cryostat, a cryogenic refrigerator that cools within the cryostat, a helium compressor that supplies compressed helium to the cryogenic refrigerator and to receive a return flow of compressed helium from the refrigerator, and a magnet supervisory system controlling operation of the magnet resonance imaging system. An apparatus is provided for controlling the speed and/or timing of operation of the helium compressor in accordance with predefined algorithms in response to system state data.

### BACKGROUND OF THE INVENTION

1. Field of the Invention

The present invention relates to superconducting magnet systems, particularly to refrigeration systems for cooling superconducting magnets. More specifically, the present invention relates to helium compressors provided for operating refrigerators used in cooling superconducting magnets, and especially to apparatus and methods provided to ensure appropriate and effective use of such helium compressors.

2. Description of the Prior Art

In a typical refrigeration arrangement for cooling a superconducting magnet, the superconducting magnet is enclosed within a cryostat, itself typically having a cryogen vessel and an outer vacuum chamber which principally serves to provide thermal insulation from ambient temperature. The superconducting magnet is typically cooled to a temperature of approximately 4K by boiling liquid helium, in any one of a number of known alternative arrangements. In order to reduce the consumption of helium, and to reduce the rate of boiling, refrigerators are typically provided, which are able to cool at about 4K, being below the boiling point of helium. This has the effect of re-condensing at least some of the boiled-off helium vapor back into liquid form. The provision of such a re-condensing refrigerator reduces the consumption of liquid helium, and allows the magnet to be kept cool for a longer time before helium refill is required.

Such re-condensing refrigerators are typically operated by alternating streams of relatively high-pressure and relatively low-pressure helium. Even the relatively low pressure helium is typically at a pressure in excess of atmospheric pressure, which helps to reduce air ingress to the system. The helium compressor drives high pressure helium gas into a remote cold head unit (refrigerator) in which heat exchange occurs delivering cooling power at 4K.

FIG. 1 shows a typical present arrangement of a magnet (not visible) within a cryostat 10, with a mechanical refrigerator 12 providing cooling to the interior of the cryostat. The refrigerator 12 is in a helium circuit that includes high pressure supply line 14, low pressure return line 16 and helium compressor 18.

A magnetic resonance imaging system will have further equipment (not illustrated), such as gradient and field coils, shim coils and a patient table. One or more system electronics cabinet(s) 20 house(s) a magnet supervisory system 22 and other control and measurement equipment 24 which control operation of the magnet, and such further equipment, over communications lines 26. The magnet supervisory system 22 receives data input from appropriate system sensors attached to various components of the MRI system. Helium compressor 18 is typically an electromechanical device. It is conventionally mechanically enclosed within the system electronics cabinet(s) 20 but the helium compressor is conventionally a standalone device.

While the magnet supervisory system 22 typically is active only when imaging procedures are being planned or carried out, refrigeration generally continues on a permanent basis. This ensures that the magnet is in an operative state as soon as it is required, and avoids excessive consumption of helium cryogen which would result if cooling by refrigerator 12 were interrupted. Helium compressor 18 is therefore typically continually active, providing compressed helium to the helium circuit and so to the refrigerator 12. The power consumption of the helium refrigeration system is accordingly constant regardless of the cooling power actually required at any particular time. The electrical power consumed by the helium refrigeration is significant, currently about approx 9 kW, which is at least costly to the user. The user may find difficulty in ensuring such an electrical power supply level, and such power consumption raises environmental concerns. The consumption of 9 kW constantly over a year may be responsible for the generation of over 41 tons of CO₂.

The helium compressor is a hard-working electromechanical device and requires regular servicing to maintain satisfactory operation. Servicing and diagnosis of the helium compressor and the refrigerator usually requires a site visit from a service engineer, and may result in down-time for the whole MRI system, not just the helium compressor Such service visits thus represent a significant cost to the user, both in terms of the actual service and site visit itself, but also the consequential system down-time.

When the helium compressor is continuously operating at full power, as is conventional, the operating life of the helium compressor and the refrigeration components is reduced, servicing is required frequently and electrical power consumption of the helium compressor is maximized.

U.S. Pat. No. 7,234,324 describes a system for helium compression and liquefaction for cooling of superconducting devices. Compressor speed is controlled according to pressure and flow rate. The compressor is speed-controlled according to a predetermined curve. It does not describe active control in the sense of the present invention.

U.S. Pat. No. 7,143,016 describes a control for a general pump, which may optimize throughput, efficiency, lifetime or other measures. The pump motor is controlled and driven according to a single set operating point as defined by a user.

European patent application EP 1 318 365 describes temperature control of a refrigerator or freezer for food storage. The temperature control is achieved by varying the speed of the compressor. Control applied to the compressor is on/off control in addition to controlled variation of the speed of the compressor when turned on.

### SUMMARY OF THE INVENTION

An object of the present invention is to increase the operating life of the helium compressor and the refrigeration components, to reduce the frequency of servicing and to reduce electrical power consumption of the helium compressor. The present invention addresses these aims by avoiding the need for the helium compressor to operate continuously.

The above object is achieved in accordance with the present invention in a magnetic resonance imaging system, and a method for controlling the speed and/or timing of operation of a helium compressor in such a magnetic resonance imaging system, wherein a superconducting magnet is housed within a cryostat, and a cryogenic refrigerator is provided that cools within the cryostat. The helium compressor supplies compressed helium to the cryogenic refrigerator and receives a return flow of compressed helium from the refrigerator. A magnet supervisory system controls operation of the magnetic resonance imaging system, and a compressor control controls the speed and/or timing of operation of the helium compressor in accordance with predetermined algorithms in response to systems date data. The compressor control has a communications and control node that communicates between the helium compressor and the magnet supervisory system to receive control commands from the magnet supervisory system, and to control the operating power of the helium compressor dependent thereon/

### BRIEF DESCRIPTION OF THE DRAWINGS

FIG. 1 as noted above, illustrates a known arrangement having a helium compressor in a system further including a refrigerator supplied by the helium compressor.

FIG. 2 illustrates an arrangement according to the present invention having a helium compressor in a system further including a refrigerator supplied by the helium compressor.

### DESCRIPTION OF THE PREFERRED EMBODIMENTS

The cooling power, and hence the helium compressor power consumption, actually required by the magnet system at any one time is dependent on many parameters including workflow schedules, gradient coil duty cycles for particular imaging sequences and atmospheric pressure changes. The present invention provides active control of the helium compressor, and hence of the refrigerator's cooling power, determined according to the cooling power actually required at that time, rather than the current approach of operating the helium compressor and the refrigerator at 100% duty cycle at all times. The control provided by the present invention may be simple on/off control of variable duty cycle, or may be by variation in the speed of the motor driving the helium compressor.

The active control of the helium compressor as provided by the present invention also provides other benefits including improved reliability of the helium compressor and the refrigerator, increased service intervals, improved service diagnostic capabilities, and in certain embodiments allows a smaller less costly motor to be used to operate the helium compressor. In certain embodiments, the present invention provides a new way of controlling cryogen pressure within the cryogen vessel.

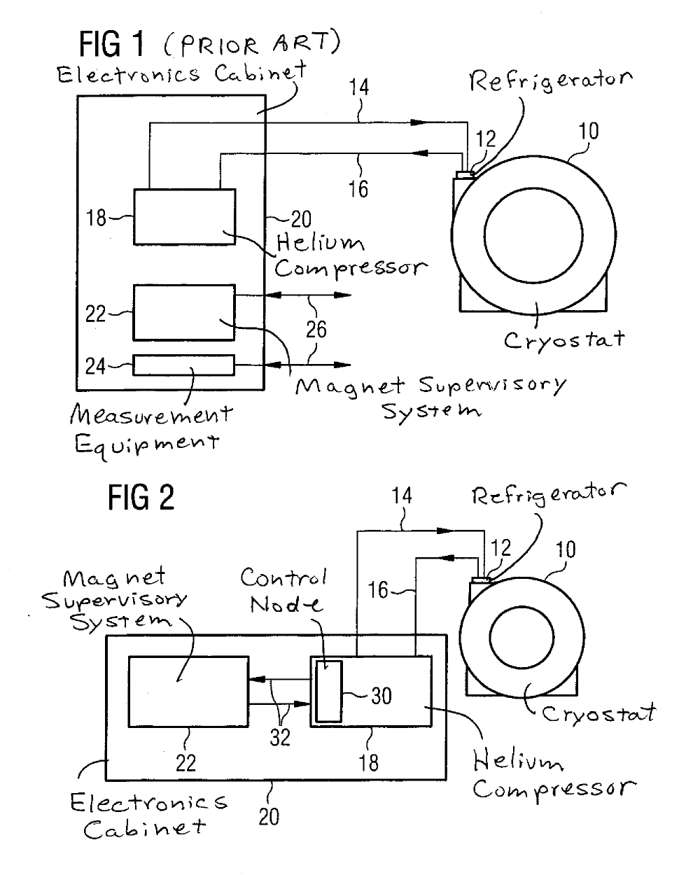

FIG. 2 illustrates an arrangement according to an embodiment of the present invention. Features common with those of FIG. 1 have common reference numerals. According to an aspect of the invention, a communications and control node 30 is added to the helium compressor 18, to enable communication between the helium compressor and the magnet supervisory system 22. The communications and control node 30 also comprises means enabling the magnet supervisory system 22 to control the operation of the helium compressor, at least in so far as to control its power consumption by varying its speed of operation and/or by turning it on and off. This preferably includes a regulated variable speed controller to enable variable cooling performance and therefore variable power consumption, as controlled by the magnet supervisory system 22.

The helium compressor is operated in accordance with a feedback loop which includes the magnet supervisory system 22 controlling the operating power of the helium compressor according to predefined algorithms. For example, the temperature or pressure of gas within the cryogen vessel may be measured by the magnet supervisory system 22 using an appropriate sensor. Alternatively, a temperature within the outer vacuum container may be measured, such as a temperature of a thermal shield positioned between the cryogen vessel and the outer vacuum container. If the measured temperature or pressure is detected to be in excess of a certain respective upper limit, the operating power of the helium compressor is increased. This may be by increasing the speed of operation of the compressor, or by turning it on, depending on whether variable speed control is provided, or simple on/off control. If the temperature or pressure is detected to be below of a certain respective lower limit, the operating power of the helium compressor is reduced. This may be by reducing the speed of operation of the compressor, or by turning it off, depending on whether variable speed control is provided, or simple on/off control.

Such arrangements, according to the present invention, allow the magnet supervisory system 22 to optimize the power drawn by the helium compressor, such that a required temperature and/or pressure is maintained within the cryogen vessel, with a reduced consumption of power by the helium compressor.

The algorithms employed to control the speed of operation of the compressor may be based on sensor output, as described above; alternatively, a required speed of operation of the compressor may be calculated or called up in response, for example, to the initiation of a certain imaging sequence.

In alternative embodiments of the present invention, the helium compressor is also provided with an onboard processing capability which receives data input from appropriate system sensors attached to certain parts of the MRI system. In such embodiments, the onboard processing capability operates according to defined algorithms, in response to data received from the system sensors.

Preferably, a variable speed controller is provided within, or associated with, the helium compressor, to enable variable cooling performance. The speed controller is arranged to receive speed control commands either from the onboard processing capability, or from the magnet supervisory system 22, or possibly both, to control the speed of operation of the helium compressor.

The present invention accordingly provides methods and apparatus for controlling the speed and/or timing of operation of the helium compressor in accordance with predefined algorithms in response to system state data, such as measurement data received from system sensors or information relating to an initiated imaging sequence. The helium compressor is provided with a communications and control node in order to enable communications between the helium compressor and the magnet supervisory system 22 and/or system sensors, in order to receive speed control commands from the magnet supervisory system 22 and/or measurement data from the system sensors, and to control the operating power of the comparator accordingly. According to some embodiments of the invention, the helium compressor is provided with an onboard processing capability to perform control on the helium processor according to predefined algorithms in response to measurement data from the system sensors. As an alternative to control by the magnet supervisory system 22, a dedicated communication and control circuit may be provided within the MRI system, specifically for receiving measurement data from the system sensors, and perform corresponding control on the helium processor according to predefined algorithms in response to the measurement data.

The present invention enables speed control of the helium compressor, reactive to system conditions, such that the helium compressor is turned off or slowed down when the MRI system does not need maximum cooling power. This allows the power consumed by the compressor, and therefore the cooling performance of the system, to be directly controlled by, or in response to, the MRI system.

For example, there are typically extended periods during which no imaging sequences are performed, such as overnight or at weekends. At these times, the magnet supervisory system 22 may enter a “standby” state. The helium compressor may then be controlled by the magnet supervisory system 22, or a separate a dedicated communication and control circuit within the MRI system, or a variable speed controller within, or associated with, the helium compressor, in a minimum power consumption mode. Such minimum power consumption mode ensures that the helium compressor is operated at a reduced speed, and/or intermittently, to an extent just sufficient to maintain a required temperature within the cryogen vessel.

Certain particular benefits of variable helium compressor speed control according to the present invention include the following.

The lifetime cost of ownership of the helium compressor, and the MRI system as a whole, is reduced due to the reduction in overall power consumption of the helium compressor. The service interval of the helium compressor and the refrigerator may be increased due to reduced wear of the helium compressor and the refrigerator. In certain embodiments, the helium compressor is provided with oil filters and/or oil adsorbers or absorbers, which remove oil from the compressed helium to prevent it reaching the refrigerator. Such filters, absorbers and adsorbers need to be regularly cleaned or replaced. The interval between cleaning or replacement may be increased as a result of controlling the helium compressor according to the present invention. Further reduction of the lifetime cost of ownership of the helium pump, and the MRI system as a whole is obtained by reducing the overall power consumption by the helium compressor. Such reduction in energy consumption may also provide environmental benefits.

By providing the described reactive control of the helium compressor, and so also of the refrigerator, they become an integrated component of the MR system, allowing more efficient control and operation of the system as a whole.

In certain embodiments of the invention, the operating power of the compressor maybe controlled in accordance with a detected pressure within the cryogen vessel. This pressure should be maintained above atmospheric pressure, to reduce air influx to the MRI system, but should not be allowed to become excessively high, which may pose a danger to the integrity of the system. In such embodiments, the helium compressor may be driven faster, or at a higher duty cycle if simple on/off control is used, to reduce the pressure within the cryogen vessel, or may be driven slower, or at a reduced duty cycle if simple on/off control is used, to increase the pressure within the cryogen vessel.

In certain embodiments, it may be found possible to use a smaller drive motor for the helium compressor. This in turn may lead to reduced initial purchase price and reduced operating costs.

The present invention accordingly provides an intelligent helium compressor which includes a variable speed controller, and a communication system to enable direct connection to the MRI system. The advantage that the helium compressor is driven according to the MRI system requirements, and need not provide maximum cooling power unless it is needed. This allows the input power drawn by the helium compressor to be minimized, as it needs to run at full power only when the MRI system demands it.

Although modifications and changes may be suggested by those skilled in the art, it is the intention of the inventors to embody within the patent warranted hereon all changes and modifications as reasonably and properly come within the scope of their contribution to the art.

We claim as our invention:

1. A magnetic resonance imaging system comprising:
a superconducting magnet housed within a cryostat; a cryogenic refrigerator that cools within the cryostat; a helium compressor that supplies compressed helium to the cryogenic refrigerator and that receives a return flow of compressed helium from the refrigerator; and a magnet supervisory system configured to control operation of the magnetic resonance imaging system; and
a compressor control configured to control the speed and/or timing of operation of the helium compressor in accordance with predefined algorithms in response to system state data, said compressor control comprising a communications and control node that communicates between the helium compressor and the magnet supervisory system to receive control commands from the magnet supervisory system and to control the operating power of the helium compressor dependent thereon.

2. A magnetic resonance imaging system according to claim 1 wherein the control commands to control the operating power of the helium compressor in accordance with requirements relating to an initiated imaging sequence.

3. A magnetic resonance imaging system according to claim 1 wherein the communications and control node additionally communicates between the helium compressor and at least one system sensor, in order to receive measurement data from the at lease one system sensor, and to control the operating power of the helium compressor according to the received measurement data.

4. A magnetic resonance imaging system according to claim 3, wherein the helium compressor is configured with an onboard processing capability arranged to perform speed and/or timing of operation control on the helium compressor according to predefined algorithms in response to measurement data from the at least one system sensor.

5. A magnetic resonance imaging system according to claim 1, wherein said compressor control is configured to control the speed and/or timing of operation of the helium compressor by varying its speed of operation and/or by turning the helium compressor on and off.

6. A magnetic resonance imaging system according to claim 1, wherein said compressor control comprises a regulated variable speed controller to produce said variable speed of operation of the helium compressor.

7. A method for controlling the speed and/or timing of operation of the helium compressor of a magnetic resonance imaging system comprising the steps of:
measuring the temperature of gas within the cryogen vessel using a sensor;
in response to the measured temperature being detected to be in excess of an upper limit, automatically, via a magnet supervisory system, increasing the operating power of the helium compressor by controlling the speed and/or timing of operation of the helium compressor; and
in response to the measured temperature being detected to be below a lower limit, automatically, via said magnet supervisory system, reducing the operating power of the helium compressor by controlling the speed and/or timing of operation of the helium compressor.

8. A method for controlling the speed and/or timing of operation of the helium compressor of a magnetic resonance imaging system according to claim 7, wherein said sensor is a first sensor, and comprising:
measuring the pressure of gas within the cryogen vessel using a second sensor;
in response to the measured pressure being detected to be in excess of an upper limit, automatically, via a magnet supervisory system, increasing the operating power of the helium compressor by controlling the speed and/or timing of operation of the helium compressor; and
in response to the measured pressure being detected to be below a lower limit, automatically, via said magnet supervisory system, reducing the operating power of the helium compressor by controlling the speed and/or timing of operation of the helium compressor.

9. A method for controlling the speed and/or timing of operation of the helium compressor of a magnetic resonance imaging system according to claim 7, wherein said sensor is a first sensor, and comprising:
measuring a temperature within the outer vacuum container using a second sensor;
in response to the measured temperature being detected to be in excess of an upper limit, automatically, via a magnet supervisory system, increasing the operating power of the helium compressor by controlling the speed and/or timing of operation of the helium compressor; and
in response to the measured temperature being detected to be below a lower limit, automatically, via said magnet supervisory system, reducing the operating power of the helium compressor by controlling the speed and/or timing of operation of the helium compressor.

10. A method for controlling the speed and/or timing of operation of the helium compressor of a magnetic resonance imaging system according to claim 7, comprising:
at times during which no imaging sequences are performed, automatically causing the magnet supervisory system to enter a standby state; and
in response to the magnet supervisory system being in the standby state, automatically controlling the speed and/or timing of operation of the helium compressor in a minimum power consumption mode, to an extent sufficient to maintain a required temperature within the cryogen vessel.

11. A method according to claim 7 comprising, using a variable speed controller associated with the helium compressor to receive speed control commands from the magnet supervisory system and to control the speed of operation of the helium compressor in accordance with the received speed control commands.

12. A method according to claim 7 comprising providing the helium compressor with onboard processing capability to receive data input from at least one system sensor, and to perform speed and/or timing of operation control on the helium compressor according to predefined algorithms in response to measurement data from the at least one system sensor.

13. A method according to claim 12 comprising using a variable speed controller associated with, the helium compressor to receive speed control commands from the onboard processing capability and to control the speed of operation of the helium compressor in accordance with the received speed control commands.
